(19) United States
(12) Patent Application Publication
(10) Pub. No.: US 2024/0395510 A1
(43) Pub. Date: Nov. 28, 2024

(54) SUBSTRATE PROCESSING APPARATUS

(71) Applicant: Tokyo Electron Limited, Tokyo (JP)

(72) Inventors: Norihiko AMIKURA, Kurokawa-gun (JP); Naoki MATSUMOTO, Kurokawa-gun (JP)

(21) Appl. No.: 18/667,079

(22) Filed: May 17, 2024

(30) Foreign Application Priority Data
May 23, 2023 (JP) 2023-084648

(51) Int. Cl. H01J 37/32

(52) U.S. Cl. CPC H01J 37/32669; H01J 37/32091; H01J 37/3244; H01J 2237/334

(57) ABSTRACT

A substrate processing apparatus includes a first annular baffle plate that is disposed between a substrate support and a sidewall of a chamber, a second annular baffle plate that is disposed to overlap the first annular baffle plate in a vertical direction and includes a first magnetic structure, and a first driving unit that is disposed outside the chamber, and includes a first actuator that is configured to rotate the first magnetic structure in a horizontal direction by rotating the second magnetic structure in the horizontal direction and to rotate the second annular baffle plate in the horizontal direction with respect to the first annular baffle plate by the rotation of the first magnetic structure in the horizontal direction.

### CROSS-REFERENCE TO RELATED APPLICATION

The present application claims priority under 35 U.S.C. § 119 to Japanese Patent Application No. 2023-084648 filed on May 23, 2023, the entire contents of which are incorporated herein by reference.

### BACKGROUND

### Field

An exemplary embodiment of the present disclosure relates to a substrate processing apparatus.

### Description of Related Art

US2018/0202045A1 discloses a technique in which an exhaust ring is driven by a gear in a chamber in a substrate processing apparatus.

### SUMMARY

A substrate processing apparatus according to one exemplary embodiment of the present disclosure includes: a chamber having a sidewall; a substrate support disposed in the chamber; a first annular baffle plate disposed between the substrate support and the sidewall of the chamber, the first annular baffle plate having an upper surface and a lower surface, the first annular baffle plate having a plurality of first openings penetrating from the upper surface to the lower surface; a second annular baffle plate disposed to overlap with the first annular baffle plate in a vertical direction, the second annular baffle plate having an upper surface, a lower surface and a first outer edge surface, the second annular baffle plate having a plurality of second opening penetrating from the upper surface to the lower surface, the second annular baffle plate including a first magnetic structure disposed on the first outer edge surface; and a first driving unit disposed outside the chamber, the first driving unit including: a second magnetic structure disposed to face the first magnetic structure via the sidewall of the chamber, and a first actuator configured to rotate the first magnetic structure in a horizontal direction by rotating the second magnetic structure in the horizontal direction and to rotate the second annular baffle plate in the horizontal direction with respect to the first annular baffle plate by the rotation of the first magnetic structure in the horizontal direction.

### BRIEF DESCRIPTION OF DRAWINGS

FIG. 1 is a view for explaining a configuration example of a plasma processing system.

FIG. 2 is a view for explaining a configuration example of a plasma processing apparatus in a first embodiment.

FIG. 3 is a view for explaining an example of a configuration of a first annular baffle plate and a second annular baffle plate.

FIG. 4 is a view for explaining an example of a configuration of the first annular baffle plate, the second annular baffle plate, and a first driving unit.

FIG. 5 is a diagram for illustrating a disposition example of a first S pole magnet and a first N pole magnet in a first magnetic structure and a disposition example of a second S pole magnet and a second N pole magnet in a second magnetic structure.

FIG. 6A is a diagram showing an example of the position adjustment of a first opening and a second opening in a case where the internal pressure of a plasma processing space is made relatively low.

FIG. 6B is a diagram showing an example of the position adjustment of the first opening and the second opening in a case where the internal pressure of the plasma processing space is made relatively high.

FIG. 6C is a diagram showing an example of the position adjustment of the first opening and the second opening in a case where the internal pressure of the plasma processing space is made moderate.

FIG. 7 is a view for explaining a configuration example of a plasma processing apparatus in a second embodiment.

FIG. 8 is a view for explaining an example of a configuration of a first annular baffle plate, a second annular baffle plate, and a second driving unit.

FIG. 9A is a diagram showing an example of distance adjustment between a first opening and a second opening in a case where the internal pressure of a plasma processing space is made relatively low.

FIG. 9B is a diagram showing an example of distance adjustment between the first opening and the second opening in a case where the internal pressure of the plasma processing space is made relatively high.

FIG. 10 is a view for explaining another configuration example of the first annular baffle plate, the second annular baffle plate, and the second driving unit.

FIG. 11 is a view for explaining an example in which the second driving unit is disposed at a plurality of locations along the sidewall of a chamber.

FIG. 12 is a view for explaining an example in which the plasma processing apparatus has a guide shaft that guides the movement of the second annular baffle plate.

FIG. 13 is a diagram showing a disposition example of a through-hole of the second annular baffle plate and a magnet provided on a guide shaft.

FIG. 14 is a view for explaining an example of a case where the plasma processing apparatus includes a first annular baffle plate, a second annular baffle plate, a lifting unit, and a second driving unit in the second embodiment.

FIG. 15 is a view for explaining a configuration example of a plasma processing apparatus in a third embodiment.

FIG. 16 is a view for explaining a configuration example of a baffle structure and a driving unit.

FIG. 17 is a view for explaining a configuration example of the baffle structure and the driving unit.

FIG. 18 is a diagram showing a disposition example of a first S pole magnet and a first N pole magnet in a first magnetic structure.

FIG. 19 is a diagram showing a disposition example of a second S pole magnet and a second N pole magnet in a second magnetic structure.

FIG. 20 is a diagram showing a state in which a body part of the baffle structure is rotated by 90° to form an opening between the body parts.

FIG. 21A is a diagram showing an example of the rotation angle adjustment of the body part in a case where the internal pressure of the plasma processing space is made relatively low.

FIG. 21B is a diagram showing an example of the rotation angle adjustment of the body part in a case where the internal pressure of the plasma processing space is made relatively high.

### DETAILED DESCRIPTION

Hereinafter, each embodiment of the present disclosure will be described.

In one exemplary embodiment, there is provided a substrate processing apparatus including: a chamber having a sidewall; a substrate support disposed in the chamber; a first annular baffle plate disposed between the substrate support and the sidewall of the chamber, the first annular baffle plate having an upper surface and a lower surface, the first annular baffle plate having a plurality of first openings penetrating from the upper surface to the lower surface; a second annular baffle plate disposed to overlap with the first annular baffle plate in a vertical direction, the second annular baffle plate having an upper surface, a lower surface and a first outer edge surface, the second annular baffle plate having a plurality of second opening penetrating from the upper surface to the lower surface, the second annular baffle plate including a first magnetic structure disposed on the first outer edge surface; and a first driving unit disposed outside the chamber, the first driving unit including: a second magnetic structure disposed to face the first magnetic structure via the sidewall of the chamber, and a first actuator configured to rotate the first magnetic structure in a horizontal direction by rotating the second magnetic structure in the horizontal direction and to rotate the second annular baffle plate in the horizontal direction with respect to the first annular baffle plate by the rotation of the first magnetic structure in the horizontal direction.

In one exemplary embodiment, the first magnetic structure includes one or more first S pole magnets and one or more first N pole magnets, the one or more first S pole magnets and the one or more first N pole magnets are alternately arranged along the horizontal direction in a first region of the first outer edge surface of the second annular baffle plate, the second magnetic structure includes a first non-contact gear, one or more second S pole magnets, and one or more second N pole magnets, the first non-contact gear has a second outer edge surface, the second outer edge surface faces the first outer edge surface of the second annular baffle plate via the sidewall of the chamber, and the one or more second S pole magnets and the one or more second N pole magnets are alternately arranged along the horizontal direction in a second region of the second outer edge surface.

In one exemplary embodiment, the first S pole magnet and the first N pole magnet have lateral dimensions of 50% or less of a lateral dimension of the second opening.

In one exemplary embodiment, the first S pole magnet and the first N pole magnet have lateral dimensions of 25% or less of a lateral dimension of the second opening.

In one exemplary embodiment, the first region has a lateral dimension substantially the same as the lateral dimension of the second opening, the one or more first S pole magnets and the one or more first N pole magnets include a plurality of first S pole magnets and a plurality of first N pole magnets, and the one or more second S pole magnets and the one or more second N pole magnets include a plurality of second S pole magnets and a plurality of second N pole magnets.

In one exemplary embodiment, the second region has a lateral dimension that is the same as or larger than the lateral dimension of the first region.

In one exemplary embodiment, the first annular baffle plate is fixed to the chamber, and the second annular baffle plate is disposed below the first annular baffle plate.

In one exemplary embodiment, a second driving unit that is disposed outside the chamber is further included, in which the second annular baffle plate includes a third magnetic structure, and the second driving unit includes: a fourth magnetic structure disposed to face the third magnetic structure via the sidewall of the chamber, and a second actuator configured to move the third magnetic structure in the vertical direction by rotating or moving the fourth magnetic structure in the vertical direction and to move the second annular baffle plate in the vertical direction with respect to the first annular baffle plate by the movement of the third magnetic structure.

In one exemplary embodiment, the third magnetic structure includes one or more third S pole magnets and one or more third N pole magnets, the one or more third S pole magnets and the one or more third N pole magnets are alternately arranged along the vertical direction in a third region of the first outer edge surface of the second annular baffle plate, the fourth magnetic structure includes a second non-contact gear, one or more fourth S pole magnets, and one or more fourth N pole magnets, the second non-contact gear has a third outer edge surface, the third outer edge surface faces the first outer edge surface of the second annular baffle plate via the sidewall of the chamber, and the one or more fourth S pole magnets and the one or more fourth N pole magnets are alternately arranged along the vertical direction in a fourth region of the third outer edge surface.

In one exemplary embodiment, a lifting unit that is disposed in the chamber and is configured to move the second annular baffle plate in the vertical direction; and a second driving unit that is disposed outside the chamber are further included, in which the lifting unit includes a third magnetic structure, the second driving unit includes: a fourth magnetic structure disposed to face the third magnetic structure via the sidewall of the chamber, and a second actuator configured to rotate the third magnetic structure in the horizontal direction by rotating the fourth magnetic structure in the horizontal direction and to move the second annular baffle plate in the vertical direction with respect to the first annular baffle plate by the rotation of the third magnetic structure.

In one exemplary embodiment, the third magnetic structure includes a second non-contact gear, one or more third S pole magnets, and one or more third N pole magnets, the second non-contact gear has a third outer edge surface, the one or the plurality of third S pole magnets and the one or the plurality of third N pole magnets are alternately arranged along the horizontal direction in a third region of the third outer edge surface of the second non-contact gear, the fourth magnetic structure includes a third non-contact gear, one or more fourth S pole magnets, and one or more fourth N pole magnets, the third non-contact gear has a fourth outer edge surface, the fourth outer edge surface faces the third outer edge surface via the sidewall of the chamber, and the one or the plurality of fourth S pole magnets and the one or the plurality of fourth N pole magnets are alternately arranged along the horizontal direction in a fourth region of the fourth outer edge surface.

In one exemplary embodiment, there is provided a substrate processing apparatus including: a chamber having a sidewall; a substrate support disposed in the chamber; a first annular baffle plate disposed between the substrate support and the sidewall of the chamber, the first annular baffle plate having an upper surface and a lower surface, the first annular baffle plate having a plurality of first openings penetrating from the upper surface to the lower surface; a second annular baffle plate disposed to overlap with the first annular baffle plate in a vertical direction, the second annular baffle plate having an upper surface, a lower surface and a first outer edge surface, the second annular baffle plate having a plurality of second openings penetrating from the upper surface to the lower surface, the second annular baffle plate including a first magnetic structure; and a driving unit disposed outside the chamber, the driving unit including: a second magnetic structure disposed to face the first magnetic structure via the sidewall of the chamber, and an actuator configured to move the first magnetic structure in the vertical direction by rotating or moving the second magnetic structure in the vertical direction and to move the second annular baffle plate in the vertical direction with respect to the first annular baffle plate by the movement of the first magnetic structure.

In one exemplary embodiment, the first magnetic structure includes one or more first S pole magnets and one or more first N pole magnets, the one or more first S pole magnets and the one or more first N pole magnets are alternately arranged along the vertical direction in a first region of the first outer edge surface of the second annular baffle plate, the second magnetic structure includes a non-contact gear, one or more second S pole magnets, and one or more second N pole magnets, the non-contact gear has a second outer edge surface, the second outer edge surface faces the first outer edge surface of the second annular baffle plate via the sidewall of the chamber, and the one or more second S pole magnets and the one or more second N pole magnets are alternately arranged along the vertical direction in a second region of the second outer edge surface.

In one exemplary embodiment, the one or more first S pole magnets and the one or more first N pole magnets include a plurality of first S pole magnets and a plurality of first N pole magnets, and the one or more second S pole magnets and the one or more second N pole magnets include a plurality of second S pole magnets and a plurality of second N pole magnets.

In one exemplary embodiment, there is provided a substrate processing apparatus including: a chamber having a sidewall; a substrate support disposed in the chamber; a first annular baffle plate disposed between the substrate support and the sidewall of the chamber, the first annular baffle plate having an upper surface and a lower surface, the first annular baffle plate having a plurality of first openings penetrating from the upper surface to the lower surface; a second annular baffle plate disposed to overlap with the first annular baffle plate in a vertical direction, the second annular baffle plate having an upper surface and a lower surface, the second annular baffle plate having a plurality of second openings penetrating from the upper surface to the lower surface; a lifting unit disposed in the chamber and configured to move the second annular baffle plate in the vertical direction, the lifting unit including a first magnetic structure; and a driving unit disposed outside the chamber, the driving unit including: a second magnetic structure disposed to face the first magnetic structure via the sidewall of the chamber, and an actuator configured to rotate the first magnetic structure in a horizontal direction by rotating the second magnetic structure in the horizontal direction and to move the second annular baffle plate in the vertical direction with respect to the first annular baffle plate by the rotation of the first magnetic structure.

In one exemplary embodiment, the first magnetic structure includes a first non-contact gear, one or more first S pole magnets, and one or more first N pole magnets, the first non-contact gear has a first outer edge surface, the one or the plurality of first S pole magnets and the one or the plurality of first N pole magnets are alternately arranged along the horizontal direction in a first region of the first outer edge surface of the first non-contact gear, the second magnetic structure includes a second non-contact gear, one or more second S pole magnets, and one or more second N pole magnets, the second non-contact gear has a second outer edge surface, the second outer edge surface faces the first outer edge surface via the sidewall of the chamber, and the one or the plurality of second S pole magnets and the one or the plurality of second N pole magnets are alternately arranged along the horizontal direction in a second region of the second outer edge surface.

In one exemplary embodiment, the one or more first S pole magnets and the one or more first N pole magnets include a plurality of first S pole magnets and a plurality of first N pole magnets, and the one or more second S pole magnets and the one or more second N pole magnets include a plurality of second S pole magnets and a plurality of second N pole magnets.

In one exemplary embodiment, there is provided a substrate processing apparatus including: a chamber having a sidewall; a substrate support disposed in the chamber; a baffle structure disposed between the substrate support and the sidewall of the chamber, the baffle structure including a plurality of baffle segments arranged along a circumferential direction, each of the plurality of baffle segments including a body having an upper surface and a lower surface, a first magnetic structure, and a rotation shaft extending in a radial direction between the body and the first magnetic structure; and a plurality of driving units respectively correspond to the plurality of baffle segments, the plurality of driving units being disposed outside the chamber, each of the plurality of driving units including a second magnetic structure and an actuator, the second magnetic structure being disposed to face the first magnetic structure via the sidewall of the chamber, the actuator being configured to rotate the first magnetic structure by rotating the second magnetic structure and to rotate the body part of the baffle structure about the rotation shaft by the rotation of the first magnetic structure.

In one exemplary embodiment, the first magnetic structure includes a first non-contact gear, one or more first S pole magnets, and one or more first N pole magnets, the first non-contact gear has a first surface facing the sidewall of the chamber, the one or the plurality of first S pole magnets and the one or the plurality of first N pole magnets are alternately arranged along a circumferential direction on the first surface of the first non-contact gear, the second magnetic structure includes a second non-contact gear, one or more second S pole magnets, and one or more second N pole magnets, the second non-contact gear has a second surface, and the second surface faces the first surface of the first non-contact gear via the sidewall of the chamber, and the one or the plurality of second S pole magnets and the one or the plurality of second N pole magnets are alternately arranged along the circumferential direction on the second surface of the second non-contact gear.

In one exemplary embodiment, the one or more first S pole magnets and the one or more first N pole magnets include a plurality of first S pole magnets and a plurality of first N pole magnets, and the one or more second S pole magnets and the one or more second N pole magnets include a plurality of second S pole magnets and a plurality of second N pole magnets.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### First Embodiment

### <Example of Plasma Processing Apparatus>

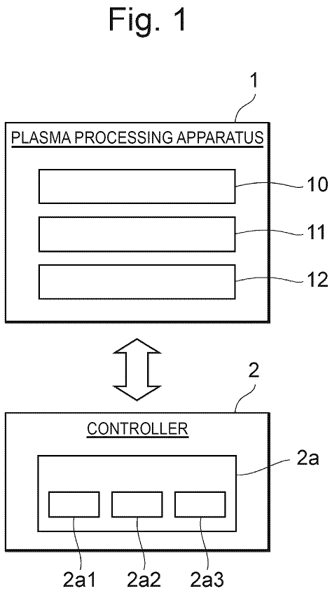

FIG. 1 is a view for explaining an example of a configuration of a capacitively-coupled plasma processing system. In one embodiment, the plasma processing system includes a plasma processing apparatus 1 and a controller 2. The plasma processing system is an example of a substrate processing system and the plasma processing apparatus 1 is an example of a substrate processing apparatus. The plasma processing apparatus 1 includes a plasma processing chamber 10, a substrate support 11 and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected the gas supply 20 to be described below, and the gas exhaust port is connected to the exhaust system 40 to be described below. The substrate support 11 is disposed in the plasma processing space and has a substrate support surface for supporting a substrate.

The plasma generator 12 is configured to generate a plasma from at least one processing gas supplied into the plasma processing space. The plasma formed in the plasma processing space may be Capacitive Coupled Plasma (CCP), Inductively Coupled Plasma (ICP), Electron-Cyclotron-resonance (ECR) plasm, Helicon Wave Plasma (HWP) or Surface Wave Plasma (SWP). Further, various types of plasma generator including Alternative Current (AC) plasma generator and Direct Current (DC) plasma generator may be used. In one embodiment, an AC signal (AC power) used in the AC plasma generator may have a frequency in the range of 100 KHz to 10 GHz. Accordingly, an AC signal may include Radio Frequency (RF) signal and Microwave signal. In one embodiment, an RF signal may have a frequency in the range of 100 kHz to 150 MHz.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

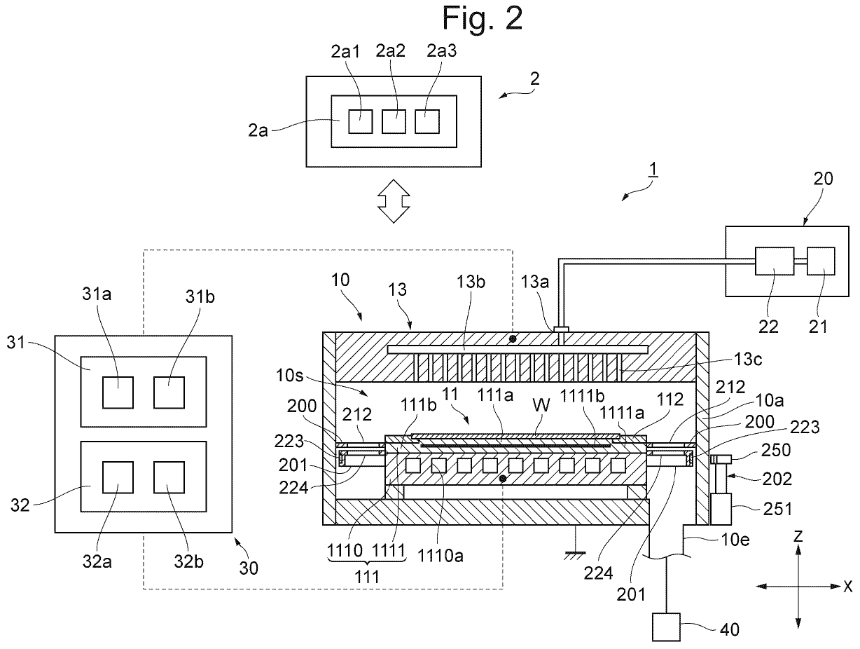

Hereinafter, an example of the configuration example of a plasma processing apparatus will be described. FIG. 2 is a view for explaining an example of a configuration of a capacitively-coupled plasma processing apparatus.

The plasma processing system includes a capacitively-coupled plasma processing apparatus 1 and a controller 2. The capacitively-coupled plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a showerhead 13. The substrate support 11 is disposed in the plasma processing chamber 10. The showerhead 13 is disposed above the substrate support 11. In one embodiment, the showerhead 13 constitutes at least a part of a ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 is grounded. The showerhead 13 and the substrate support 11 are electrically insulated from a housing of the plasma processing chamber 10.

The substrate support 11 includes a main body 111 and a ring assembly 112. The main body 111 has a central region 111a for supporting the substrate W and an annular region 111b for supporting the ring assembly 112. The wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 functions as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a central region 111a. In one embodiment, the ceramic member 1111a also has an annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 and/or a direct current (DC) power source 32 to be described below may be disposed inside the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between the rear surface of the substrate W and the central region 111a.

The showerhead 13 is configured to introduce at least one processing gas from the gas supply 20 into the plasma processing space 10s. The showerhead 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the showerhead 13 includes at least one upper electrode. The gas introduction unit may include, in addition to the showerhead 13, one or a plurality of side gas injectors (SGI) that are attached to one or a plurality of openings formed in the sidewall 10a.

The gas supply 20 may include at least one gas source 21 and at least one flow controller 22. In one embodiment, the gas supply 20 is configured to supply at least one processing gas from the respective corresponding gas sources 21 to the showerhead 13 via the respective corresponding flow controllers 22. Each flow controller 22 may include, for example, a mass flow controller or a pressure-controlled flow controller. Further, the gas supply 20 may include at least one flow modulation devices that modulate or pulse flow rates of at least one processing gas.

The power source 30 includes an RF power source 31 coupled to plasma processing chamber 10 via at least one impedance matching circuit. The RF power source 31 is configured to supply at least one RF signal (RF power) to at least one lower electrode and/or at least one upper electrode. As a result, a plasma is formed from at least one processing gas supplied into the plasma processing space 10s. Accordingly, the RF power source 31 may function as at least a portion of the plasma generator 12. Further, by supplying the bias RF signal (bias signal) to the at least one lower electrode, a bias potential (bias power) is generated in the substrate W, making it possible to draw ion components in the formed plasma into the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first DC signal is applied to at least one lower electrode. In one embodiment, the second DC generator 32b is configured to be connected to at least one upper electrode to generate a second DC signal. The generated second DC signal is applied to at least one upper electrode.

In various embodiments, at least one of the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The plasma processing apparatus 1 may include a first annular baffle plate 200, a second annular baffle plate 201, and a first driving unit 202.

The first annular baffle plate 200 and the second annular baffle plate 201 may be disposed between the substrate support 11 and the sidewall 10a of the chamber 10. The second annular baffle plate 201 may overlap the first annular baffle plate 200 in the vertical direction Z and may be disposed below the first annular baffle plate 200.

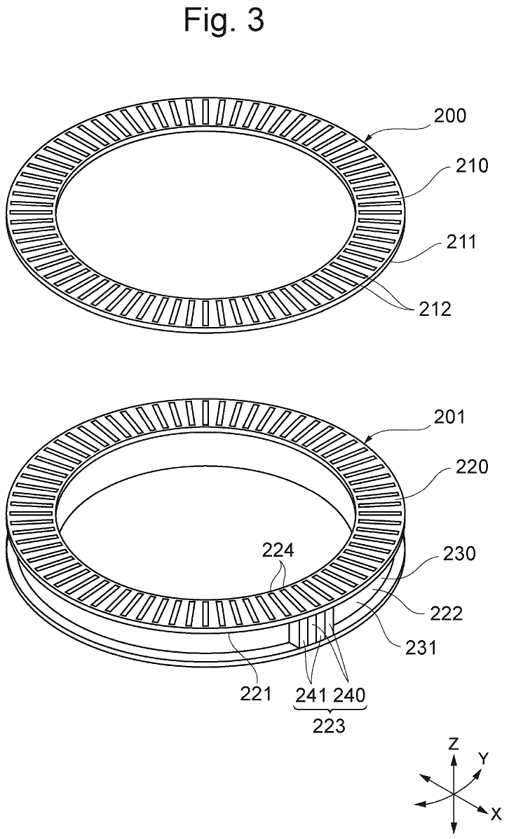

FIG. 3 is a diagram illustrating an example of configurations of the first annular baffle plate 200 and the second annular baffle plate 201. In FIG. 3, the first annular baffle plate 200 and the second annular baffle plate 201 are shown separately for the sake of description. As shown in FIG. 3, the first annular baffle plate 200 may include an upper surface 210 and a lower surface 211. A plurality of first openings 212 that penetrate from the upper surface 210 to the lower surface 211 may be formed in the first annular baffle plate 200. The plurality of first openings 212 may be disposed side by side in the horizontal direction (circumferential direction) Y over the entire circumference of the first annular baffle plate 200. The plurality of first openings 212 may be disposed at equal intervals in the circumferential direction Y. Each first opening 212 may have a substantially rectangular slit shape long in the radial direction X in plan view. The first annular baffle plate 200 may be fixed to the substrate support 11 or the chamber 10.

The second annular baffle plate 201 may include an upper surface 220, a lower surface 221, a first outer edge surface 222, and a first magnetic structure 223. A plurality of second openings 224 that penetrate from the upper surface 220 to the lower surface 221 may be formed in the second annular baffle plate 201. The plurality of second openings 224 may be disposed side by side in the circumferential direction Y over the entire circumference of the second annular baffle plate 201. The plurality of second openings 224 may be disposed at equal intervals in the circumferential direction Y. Each second opening 224 may have a substantially rectangular slit shape long in the radial direction X in plan view. The number of second openings 224 may be the same number of first openings 212, and each second opening 224 may have the same shape and the same size as the first opening 212. The second annular baffle plate 201 may be rotatably attached to the substrate support 11 or the chamber 10 in the circumferential direction Y.

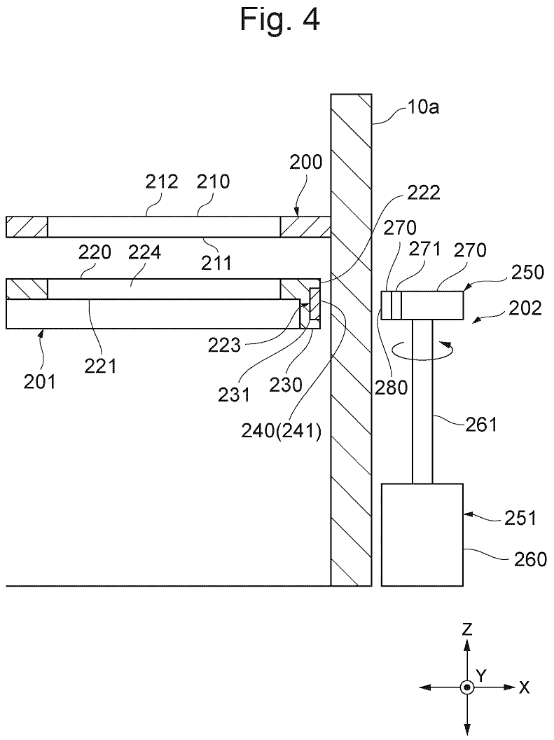

As shown in FIGS. 3 and 4, the second annular baffle plate 201 may include an annular outer peripheral portion 230 that is disposed close to the sidewall 10a of the chamber 10. The annular outer peripheral portion 230 may have a circular cylinder shape. The annular outer peripheral portion 230 may be provided to extend downward from the outermost peripheries of the upper surface 220 and the lower surface 221. The first outer edge surface 222 may be an outer peripheral surface of the annular outer peripheral portion 230. The first outer edge surface 222 (outer side surface of the annular outer peripheral portion 230) may have an annular recessed portion 231 recessed inward. The first outer edge surface 222 may be close to the inner surface of the sidewall 10a of the chamber 10.

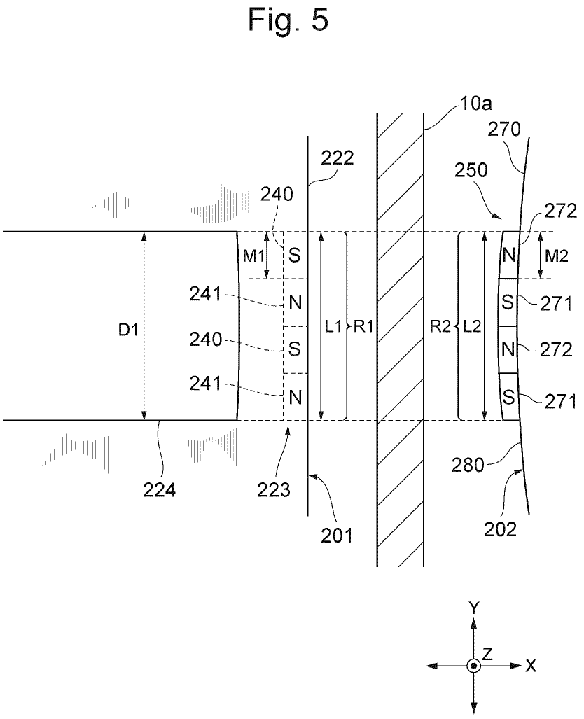

The first magnetic structure 223 may include one or more first S pole magnets 240 and one or more first N pole magnets 241. The first S pole magnet 240 and the first N pole magnet 241 may be disposed in the annular recessed portion 231 of the first outer edge surface 222. As shown in FIG. 5, the first S pole magnet 240 and the first N pole magnet 241 may be alternately arranged along the horizontal direction (circumferential direction) Y in the first region R1 of the first outer edge surface 222.

The first region R1 may have a lateral dimension L1 substantially the same as the lateral dimension D1 of the second opening 224. The first S pole magnet 240 and the first N pole magnet 241 may have a lateral dimension M1 of 50% or less of the lateral dimension D1 of the second opening 224. In this case, at least two or more of the first S pole magnets 240 and the first N pole magnets 241 (one or more first S pole magnets 240 and one or more first N pole magnets 241) may be disposed in the first region R1. The first S pole magnet 240 and the first N pole magnet 241 may have a lateral dimension M1 of 25% or less of the lateral dimension D1 of the second opening 224. In this case, at least four or more of the first S pole magnets 240 and the first N pole magnets 241 (two or more first S pole magnets 240 and two or more first N pole magnets 241) may be disposed in the first region R1.

As shown in FIGS. 2 and 4, the first driving unit 202 may be disposed outside the chamber 10. The first driving unit 202 may be disposed in the vicinity of the sidewall 10a of the chamber 10. The first driving unit 202 may include the second magnetic structure 250 and the first actuator 251.

As shown in FIG. 4, the first actuator 251 may be able to rotate the second magnetic structure 250 in the horizontal direction. The first actuator 251 may include a motor 260 and a shaft 261 that is rotated by the motor 260. The shaft 261 may be provided to extend in the vertical direction Z and may have a rotation shaft that is directed in the vertical direction Z.

The second magnetic structure 250 may be fixed to the shaft 261. The second magnetic structure 250 may include a first non-contact gear 270, one or more second S pole magnets 271, and one or more second N pole magnets 272.

The first non-contact gear 270 may have a second outer edge surface 280. The first non-contact gear 270 may have a cylindrical shape in which a center axis is directed in the vertical direction Z. The second outer edge surface 280 may face the first magnetic structure 223 via the sidewall 10a of the chamber 10. The second outer edge surface 280 may be close to an outer surface of the sidewall 10a of the chamber 10.

As shown in FIG. 5, the second S pole magnet 271 and the second N pole magnet 272 may be alternately arranged along the horizontal direction in the second region R2 of the second outer edge surface 280.

The second region R2 may have a lateral dimension L2 substantially the same as the lateral dimension D1 of the second opening 224. The second S pole magnet 271 and the second N pole magnet 272 may have the same lateral dimension M2 as the first S pole magnet 240 and the first N pole magnet 241. The second S pole magnet 271 and the second N pole magnet 272 may have a lateral dimension M2 of 50% or less of the lateral dimension D1 of the second opening 224.

In this case, at least two or more of the second S pole magnets 271 and the second N pole magnets 272 (one or more second S pole magnets 271 and one or more second N pole magnets 272) may be disposed in the second region R2. The second S pole magnet 271 and the second N pole magnet 272 may have a lateral dimension M2 of 25% or less of the lateral dimension D1 of the second opening 224. In this case, at least four or more of the second S pole magnets 271 and the second N pole magnets 272 (two or more second S pole magnets 271 and two or more second N pole magnets 272) may be disposed in the second region R2. The second region R2 may have a lateral dimension L2 that is the same as or larger than the lateral dimension L1 of the first region R1. The second S pole magnet 271 may face the first N pole magnet 241, and the second N pole magnet 272 may face the first S pole magnet 240. The numbers of the second S pole magnets 271 and the second N pole magnets 272 may be the same as or may be different from the numbers of the first S pole magnets 240 and the first N pole magnets 241.

The first actuator 251 may be able to rotate the first magnetic structure 223 in the horizontal direction Y by rotating the second magnetic structure 250 in the horizontal direction, and may be able to rotate the second annular baffle plate 201 in the horizontal direction Y with respect to the first annular baffle plate 200 by the rotation of the first magnetic structure 223 in the horizontal direction.

### <Example of Plasma Processing Method>

The plasma processing method includes an etching process of etching the film on the substrate W using a plasma. In the embodiment, the plasma processing method is executed by a controller 2 in the plasma processing apparatus 1.

First, the substrate W is transported into the chamber 10 by the transport arm, placed on the substrate support 11 by the lifter, and is held by suction on the substrate support 11 as shown in FIG. 2.

Next, the processing gas is supplied to the showerhead 13 by the gas supply 20, and is supplied from the showerhead 13 to the plasma processing space 10s. The processing gas supplied at this time includes a gas that generates an active species required for the etching process of the substrate W.

One or more RF signals are supplied from the RF power source 31 to the upper electrode and/or the lower electrode. The atmosphere in the plasma processing space 10s may be exhausted from the gas exhaust port 10e, and the inside of the plasma processing space 10s may be depressurized. As a result, the plasma is generated from the processing gas on the substrate support 11 in the plasma processing space 10s, and the substrate W is etched.

The plasma is generated in the plasma processing space 10s above the first annular baffle plate 200 and the second annular baffle plate 201. The atmosphere of the plasma processing space 10s descends through the first opening 212 of the first annular baffle plate 200 and the second opening 224 of the second annular baffle plate 201, and is exhausted to the outside of the chamber 10 from the gas exhaust port 10e.

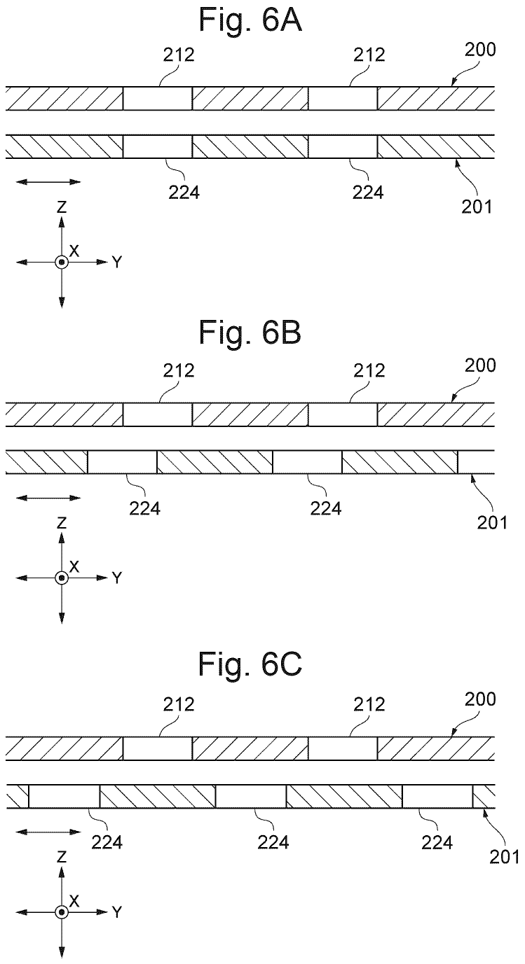

The pressure in the plasma processing space 10s is adjusted by changing the relative positions of the first opening 212 of the first annular baffle plate 200 and the second opening 224 of the second annular baffle plate 201 in the circumferential direction Y. As shown in FIG. 6A, in a case where the internal pressure of the plasma processing space 10s is adjusted to be relatively low, the positions of the first opening 212 and the second opening 224 in the circumferential direction Y may be aligned with each other. In this case, the opening ratio of the first opening 212 may be 100% in a plan view. As shown in FIG. 6B, in a case where the internal pressure of the plasma processing space 10s is adjusted to be relatively high, the positions of the first opening 212 and the second opening 224 in the circumferential direction Y may be shifted from each other. In this case, the opening ratio of the first opening 212 may be 0% in a plan view. As shown in FIG. 6C, in a case where the internal pressure of the plasma processing space 10s is adjusted to be moderate, the positions of the first opening 212 and the second opening 224 in the circumferential direction Y may be partially shifted from each other. In this case, the opening ratio of the first opening 212 may be 50% in a plan view.

In this case, the second magnetic structure 250 rotates in the horizontal direction by the first actuator 251 shown in FIG. 4. Then, the first magnetic structure 223 in the chamber 10 rotates in the horizontal direction Y by the magnetic force of the second magnetic structure 250. As a result, the second annular baffle plate 201 is rotated in the horizontal direction Y, and the positions of the first opening 212 and the second opening 224 in the circumferential direction Y are adjusted.

According to the present exemplary embodiment, the plasma processing apparatus 1 includes the first annular baffle plate 200, the second annular baffle plate 201 having the first magnetic structure 223, and the first driving unit 202 disposed outside the chamber 10. The first driving unit 202 includes a first actuator 251 configured to rotate the first magnetic structure 223 in the horizontal direction Y by rotating the second magnetic structure 250 in the horizontal direction and to rotate the second annular baffle plate 201 in the horizontal direction Y with respect to the first annular baffle plate 200 by the rotation of the first magnetic structure 223 in the horizontal direction Y. As a result, in a plasma processing apparatus including a baffle structure, it is possible to reduce contamination in the chamber 10 because it is not necessary to dispose a gear in the chamber 10 or to use grease for the gear in the chamber 10 in order to drive the second annular baffle plate 201.

### Second Embodiment

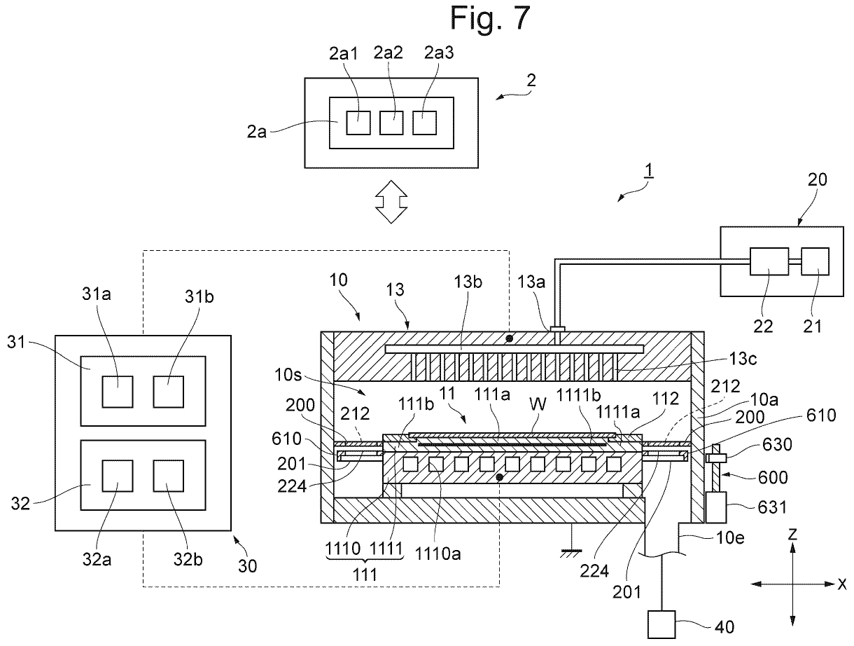

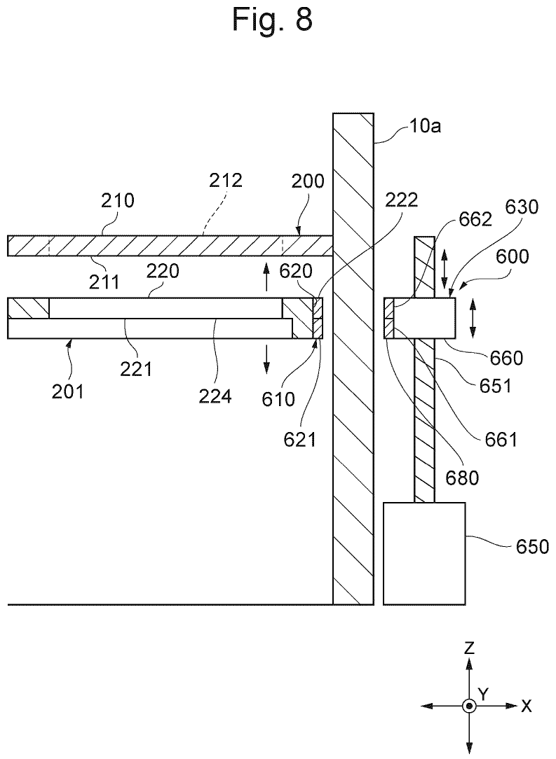

FIG. 7 is a view for explaining a configuration example of a plasma processing apparatus 1 in a second embodiment. FIG. 8 is a view for explaining an example of a configuration of a first annular baffle plate, a second annular baffle plate, and a second driving unit. As shown in FIGS. 7 and 8, the plasma processing apparatus 1 may include a first annular baffle plate 200, a second annular baffle plate 201, and a second driving unit 600.

The first annular baffle plate 200 may be the same as that of the first embodiment. That is, the first annular baffle plate 200 may include an upper surface 210, a lower surface 211, and a plurality of first openings 212.

The second annular baffle plate 201 may include an upper surface 220, a lower surface 221, a first outer edge surface 222, and a plurality of second openings 224, as in the first embodiment. The second annular baffle plate 201 may include a third magnetic structure 610. The positions of the second opening 224 and the first opening 212 in the circumferential direction Y may be shifted from each other. The second annular baffle plate 201 may be attached to the substrate support 11 or the chamber 10 so as to be movable in the vertical direction Z.

As shown in FIG. 8, the third magnetic structure 610 may include one or more third S pole magnets 620 and one or more third N pole magnets 621. The third S pole magnet 620 and the third N pole magnet 621 may be alternately arranged along the vertical direction Z in the third region of the first outer edge surface 222.

The second driving unit 600 may be disposed outside the chamber 10. The second driving unit 600 may be disposed in the vicinity of the sidewall 10a of the chamber 10. The second driving unit 600 may include a fourth magnetic structure 630 and a second actuator 631.

The second actuator 631 may be able to move the fourth magnetic structure 630 in the vertical direction Z. The second actuator 631 may include a motor 650 and a ball screw 651. A screw axis of the ball screw 651 may be provided to extend in the vertical direction.

The fourth magnetic structure 630 may include a second non-contact gear 660, one or more fourth S pole magnets 661, and one or more fourth N pole magnets 662.

The second non-contact gear 660 may have a third outer edge surface 680. The second non-contact gear 660 may have a cylindrical shape in which a center axis is directed in the vertical direction Z. The second non-contact gear 660 may be a nut portion of the ball screw 651 that moves. The third outer edge surface 680 may face the third magnetic structure 610 via the sidewall 10a of the chamber 10. The third outer edge surface 680 may be close to an outer surface of the sidewall 10a of the chamber 10.

The fourth S pole magnet 661 and the fourth N pole magnet 662 may be alternately arranged along the vertical direction Z in the third region R3 of the third outer edge surface 680. The fourth S pole magnet 661 may face the third N pole magnet 621, and the fourth N pole magnet 662 may face the third S pole magnet 620. The numbers of the fourth S pole magnets 661 and the fourth N pole magnets 662 may be the same as or may be different from the numbers of the third S pole magnets 620 and the third N pole magnets 621.

The second actuator 631 may be able to move the third magnetic structure 610 in the vertical direction Z by moving the fourth magnetic structure 630 in the vertical direction Z, and may be able to move the second annular baffle plate 201 in the vertical direction Z with respect to the first annular baffle plate 200 by the movement of the third magnetic structure 610.

The configuration of the other plasma processing apparatus 1 may be the same as that of the first embodiment.

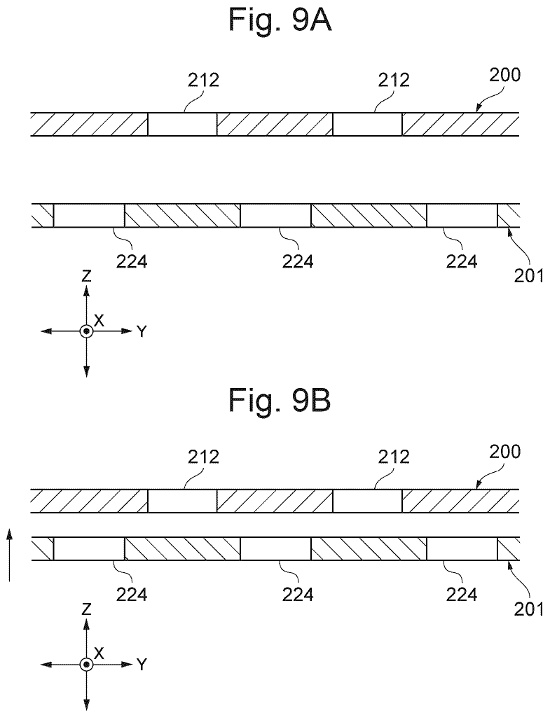

The pressure in the plasma processing space 10s during the plasma processing is adjusted by changing the distance in the vertical direction Z between the first opening 212 of the first annular baffle plate 200 and the second opening 224 of the second annular baffle plate 201. As shown in FIG. 9A, in a case where the internal pressure of the plasma processing space 10s is adjusted to be relatively low, the distance between the first opening 212 and the second opening 224 in the vertical direction Z may be separated. As shown in FIG. 9B, in a case where the internal pressure of the plasma processing space 10s is adjusted to be relatively high, the distance between the first opening 212 and the second opening 224 in the vertical direction Z may be made close.

At this time, the fourth magnetic structure 630 is moved in the vertical direction Z by the second actuator 631 shown in FIG. 7 or 8. Then, the third magnetic structure 610 in the chamber 10 moves in the vertical direction Z by the magnetic force of the fourth magnetic structure 630. As a result, the second annular baffle plate 201 is moved in the vertical direction Z, and the distance between the first opening 212 and the second opening 224 in the vertical direction Z is adjusted.

According to the exemplary embodiment, the plasma processing apparatus 1 includes the first annular baffle plate 200, the second annular baffle plate 201 having the third magnetic structure 610, and the second driving unit 600 disposed outside the chamber 10. The second driving unit 600 includes a second actuator 631 that moves the third magnetic structure 610 in the vertical direction Z by moving the fourth magnetic structure 630 in the vertical direction Z and moves the second annular baffle plate 201 in the vertical direction with respect to the first annular baffle plate 200 by the movement of the third magnetic structure 610. As a result, in a plasma processing apparatus including a baffle structure, it is possible to reduce contamination in the chamber 10 because it is not necessary to dispose a gear in the chamber 10 or to use grease for the gear in the chamber 10 in order to drive the second annular baffle plate 201.

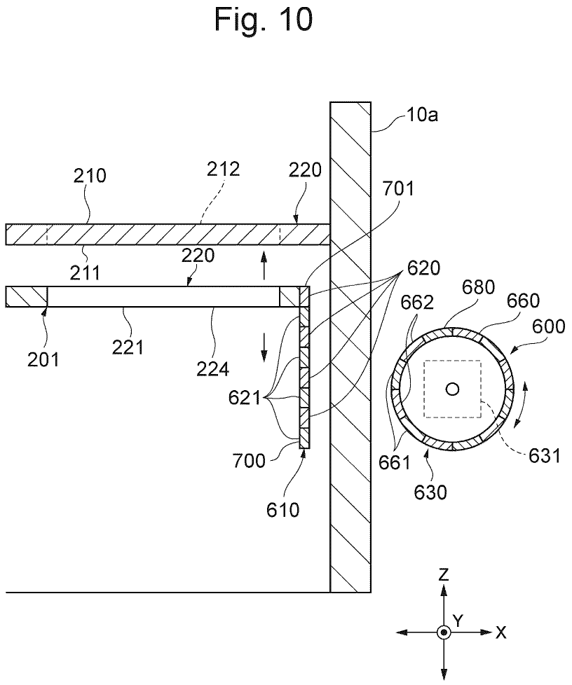

In the second embodiment, as shown in FIG. 10, the third magnetic structure 610 may include a plate 700 extending in the vertical direction Z. The plate 700 may extend downward from the outer end portion of the second annular baffle plate 201. The plate 700 may be disposed in the vicinity of the sidewall 10a along the sidewall 10a of the chamber 10.

The third S pole magnet 620 and the third N pole magnet 621 may be alternately arranged along the vertical direction Z on the first outer edge surface 701 of the plate 700.

The second non-contact gear 660 of the fourth magnetic structure 630 may have a cylindrical shape in which a center axis is directed in the circumferential direction Y along the sidewall 10a of the chamber 10. The fourth S pole magnet 661 and the fourth N pole magnet 662 may be alternately arranged along the circumferential direction (the vertical direction) in the third outer edge surface 680 of the second non-contact gear 660.

The second actuator 631 may be able to move the third magnetic structure 610 in the vertical direction Z by rotating the fourth magnetic structure 630 in the vertical direction Z, and may be able to move the second annular baffle plate 201 in the vertical direction Z with respect to the first annular baffle plate 200 by the movement of the third magnetic structure 610.

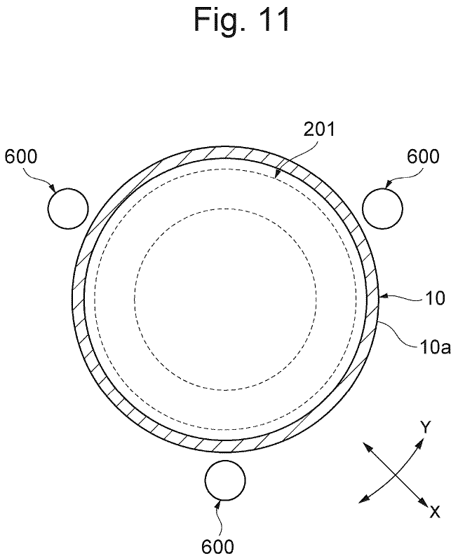

In the second embodiment described above, as shown in FIG. 11, the second driving unit 600 may be disposed at a plurality of locations along the sidewall 10a of the chamber 10. Three or more second driving units 600 may be disposed. The second driving unit 600 may be disposed at equal intervals along the circumferential direction Y of the sidewall 10a of the chamber 10. In this case, the inclination or the misalignment of the second annular baffle plate 201 is suppressed. Further, the second annular baffle plate 201 can be appropriately supported by the plurality of second driving units 600.

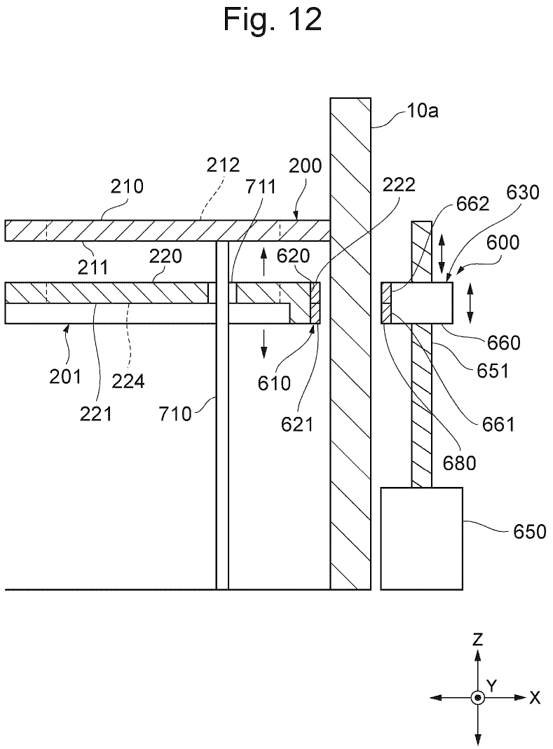

In the second embodiment described above, as shown in FIG. 12, the plasma processing apparatus 1 may have a guide shaft 710 that guides the movement of the second annular baffle plate 201 in the vertical direction Z. The second annular baffle plate 201 may have a through-hole 711 that penetrates in the vertical direction Z. The guide shaft 710 may pass through the through-hole 711 in the vertical direction Z. The guide shaft 710 may have an upper end fixed to the first annular baffle plate 200 and a lower end fixed to the bottom wall of the chamber 10.

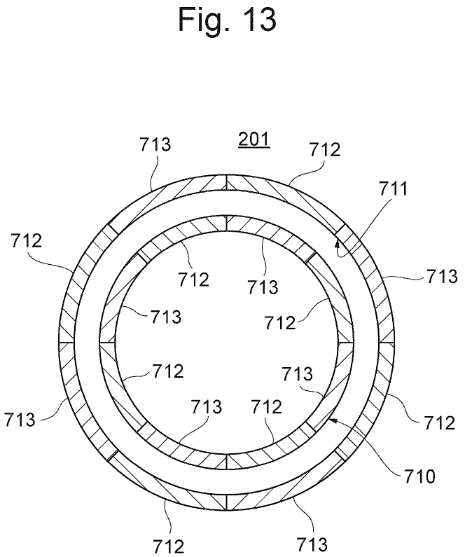

As shown in FIG. 13, the magnet may be disposed on the inner surface of the through-hole 711 and the outer surface of the guide shaft 710 so as not to approach each other. An S pole magnet 712 and an N pole magnet 713 may be alternately arranged in a circumferential direction on the inner surface of the through-hole 711 and the outer surface of the guide shaft 710, respectively.

In this case, since the second annular baffle plate 201 moves in the vertical direction Z along the guide shaft 710, the position of the second annular baffle plate 201 is prevented from being shifted. Thus, the second annular baffle plate 201 is appropriately moved by the third magnetic structure 610 and the fourth magnetic structure 630.

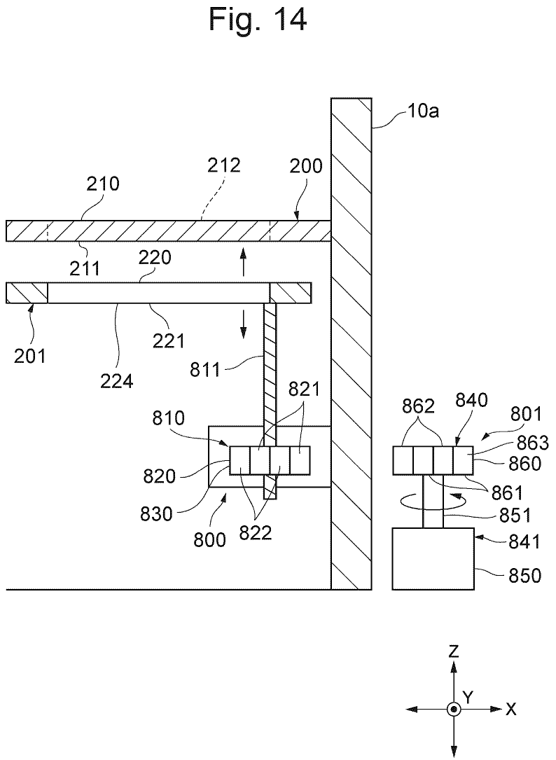

As shown in FIG. 14, the plasma processing apparatus 1 according to the second embodiment may include a first annular baffle plate 200, a second annular baffle plate 201, a lifting unit 800, and a second driving unit 801.

The lifting unit 800 may be disposed in the chamber 10. The lifting unit 800 may be able to move the second annular baffle plate 201 in the vertical direction Z. The lifting unit 800 may include a third magnetic structure 810. The lifting unit 800 may include a shaft 811 with a screw. The shaft 811 may be fixed to the second annular baffle plate 201. The shaft 811 may be provided to extend downward from the second annular baffle plate 201. The third magnetic structure 810 may be attached to the shaft 811. The third magnetic structure 810 may include a second non-contact gear 820, one or more third S pole magnets 821, and one or more third N pole magnets 822. The second non-contact gear 820 may have a third outer edge surface 830. The second non-contact gear 820 may have a cylindrical shape in which a center axis is directed in the vertical direction Z. The third outer edge surface 830 may be close to the inner surface of the sidewall 10a of the chamber 10.

One or more the third S pole magnet 821 and one or more the third N pole magnet 822 may be alternately arranged along the horizontal direction in the third region of the third outer edge surface 830 of the second non-contact gear 820. The third region may be the entire circumference of the third outer edge surface 830 of the annular shape.

The second driving unit 801 may be disposed outside the chamber 10. The second driving unit 801 may be disposed in the vicinity of the sidewall 10a of the chamber 10. The second driving unit 801 may include the fourth magnetic structure 840 and the second actuator 841.

The second actuator 841 may be able to rotate the fourth magnetic structure 840 in the horizontal direction. The second actuator 841 may include a motor 850 and a shaft 851 that is rotated by the motor 850. The shaft 851 may be provided to extend in the vertical direction and may have a rotation shaft that is directed in the vertical direction.

The fourth magnetic structure 840 may be fixed to the shaft 851. The fourth magnetic structure 840 may include a third non-contact gear 860, one or more fourth S pole magnets 861, and one or more fourth N pole magnets 862.

The third non-contact gear 860 may have a fourth outer edge surface 863. The third non-contact gear 860 may have a cylindrical shape in which a center axis is directed in the vertical direction Z. The fourth outer edge surface 863 may face the third magnetic structure 810 through the sidewall 10a of the chamber 10. The fourth outer edge surface 863 may be close to the outer surface of the sidewall 10a of the chamber 10.

The fourth S pole magnet 861 and the fourth N pole magnet 862 may be alternately arranged along the horizontal direction in the fourth region of the fourth outer edge surface 863. The fourth region may be the entire circumference of the fourth outer edge surface 863 of the annular shape. The numbers of the fourth S pole magnets 861 and the fourth N pole magnets 862 may be the same as or may be different from the numbers of the third S pole magnets 821 and the third N pole magnets 822.

The second actuator 841 may be able to rotate the third magnetic structure 810 in the chamber 10 in the horizontal direction by rotating the fourth magnetic structure 840 in the horizontal direction, and be able to move the second annular baffle plate 201 in the vertical direction Z with respect to the first annular baffle plate 200 via the shaft 851 by the rotation of the third magnetic structure 810 in the horizontal direction.

The plasma processing apparatus 1 may include both a mechanism that moves the second annular baffle plate 201 described in the second embodiment in the vertical direction Z and a mechanism that rotates the second annular baffle plate 201 described in the first embodiment in the horizontal direction Y.

### Third Embodiment

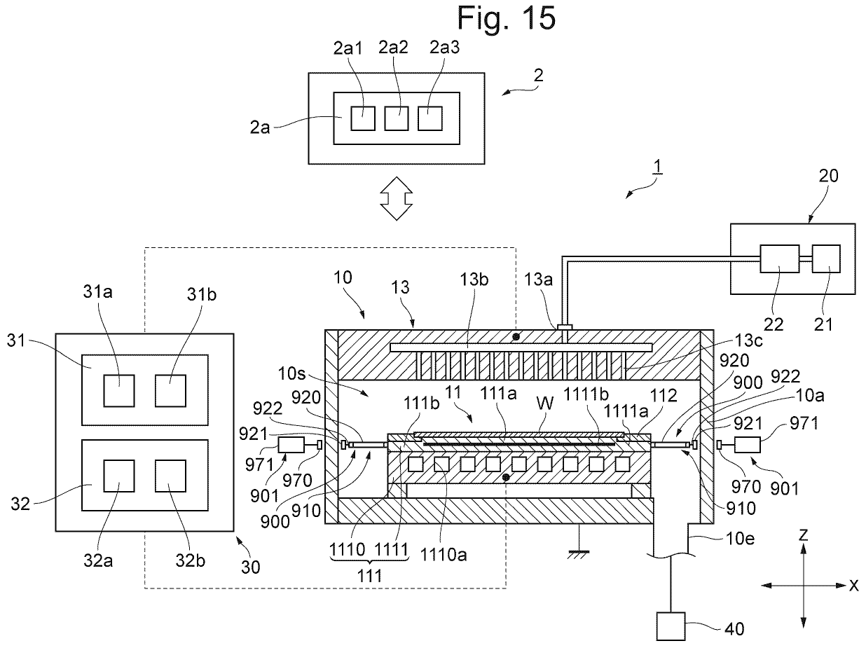

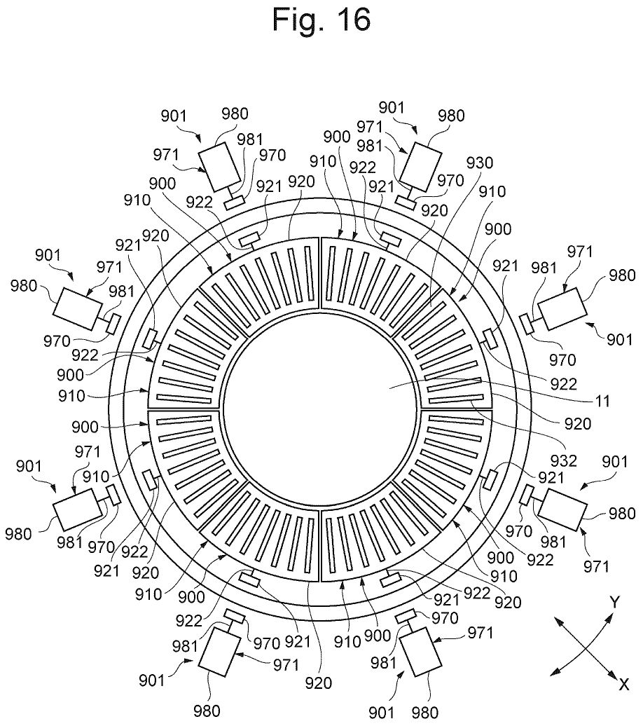

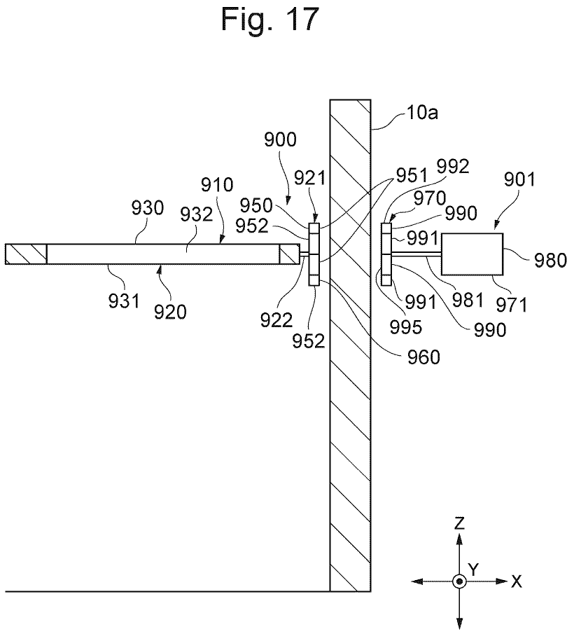

FIG. 15 is a view for explaining a configuration example of a plasma processing apparatus in a third embodiment. FIG. 16 is a view for explaining a configuration example of the baffle structure and the driving unit. FIG. 16 is a view showing a case where the chamber is cut along a horizontal plane. FIG. 17 is a view for explaining a configuration example of the baffle structure and the driving unit. FIG. 17 is a view showing a case where the chamber is cut along a vertical plane.

As shown in FIGS. 15 to 17, the plasma processing apparatus 1 may include a baffle structure 900 and a plurality of driving units 901.

The baffle structure 900 may be disposed between the substrate support 11 and the sidewall 10a of the chamber 10.

As shown in FIG. 16, the baffle structure 900 may include a plurality of baffle segments 910 arranged along the circumferential direction Y. Each of the plurality of the baffle segments 910 may include a body part 920, a first magnetic structure 921, and a rotation shaft 922 that extends between the body part 920 and the first magnetic structure 921 along the radial direction X.

The body part 920 may include an upper surface 930 and a lower surface 931. The body part 920 may have a fan shape obtained by dividing an annular plate. The body part 920 may have a shape surrounded by two arcuate sides having the same center and different diameters and two sides that connect both ends of the two arcuate sides to each other and are provided to extend in a radial direction. One or more openings 932 that penetrate from the upper surface 930 to the lower surface 931 may be formed in the body part 920. The plurality of openings 932 may be disposed side by side in the circumferential direction Y of the body part 920. The plurality of openings 932 may be disposed at equal intervals in the circumferential direction Y. Each opening 932 may have a substantially rectangular slit shape long in the radial direction X in a plan view.

The rotation shaft 922 may extend from the center of the body part 920 in the circumferential direction Y toward the outside in the radial direction X. The rotation shaft 922 may extend in a horizontal direction. The rotation shaft 922 may be connected between the body part 920 and the first magnetic structure 921.

As shown in FIG. 17, the first magnetic structure 921 may include a first non-contact gear 950, one or more first S pole magnets 951, and one or more first N pole magnets 952.

The first non-contact gear 950 may have a first surface 960. The first non-contact gear 950 may have a disk shape in which a plate surface is directed in the radial direction X. A first surface 960 of the first non-contact gear 950 may be close to an inner surface of the sidewall 10a of the chamber 10.

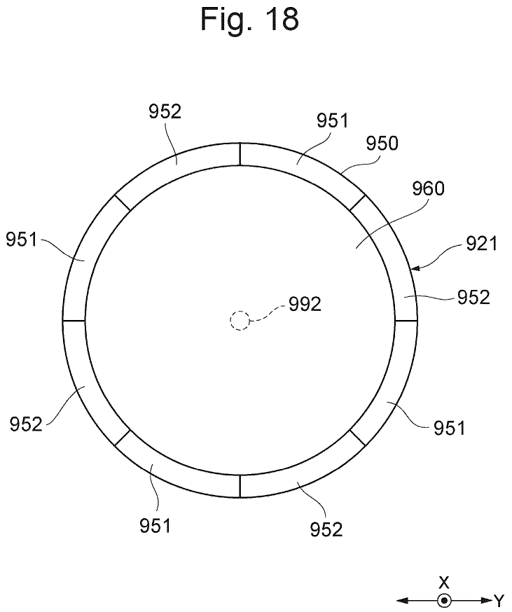

As shown in FIG. 18, the first S pole magnet 951 and the first N pole magnet 952 may be alternately arranged along the circumferential direction Y on the first surface 960. The first S pole magnet 951 and the first N pole magnet 952 may be disposed over the entire circumference of the first surface 960.

As shown in FIG. 16, the driving units 901 may be disposed outside the chamber 10 to correspond to the plurality of the baffle segments 910, respectively.

As shown in FIGS. 16 and 17, the driving unit 901 may include a second magnetic structure 970 and an actuator 971.

The actuator 971 may be able to rotate the second magnetic structure 970. The actuator 971 may include a motor 980 and a rotation shaft 981 that is rotated by the motor 980. The rotation shaft 981 may be provided on an extension line of the rotation shaft 922 and may extend in the horizontal direction of the radial direction X.

As shown in FIG. 17, the second magnetic structure 970 may be fixed to the tip of the rotation shaft 981. The second magnetic structure 970 may include a second non-contact gear 990, one or more second S pole magnets 991, and one or more second N pole magnets 992.

The second non-contact gear 990 may have a second surface 995. The second non-contact gear 990 may have a disk shape in which a plate surface is directed in the radial direction X. The second surface 995 may face the first magnetic structure 921 via the sidewall 10a of the chamber 10. The second surface 995 may be close to an outer surface of the sidewall 10a of the chamber 10.

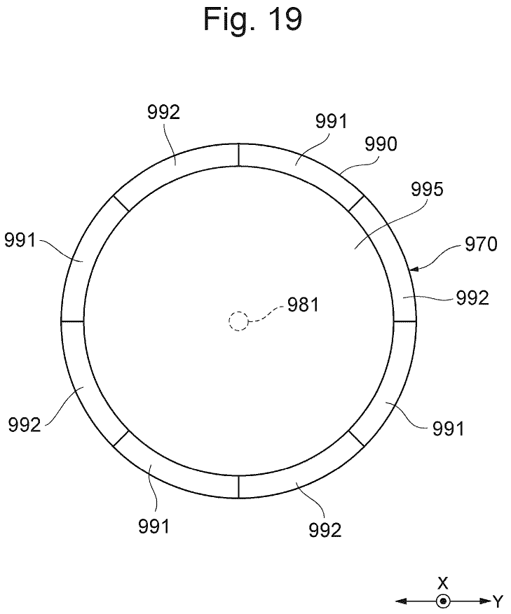

As shown in FIG. 19, the second S pole magnet 991 and the second N pole magnet 992 may be alternately arranged along the circumferential direction on the second surface 995. The second S pole magnet 991 and the second N pole magnet 992 may be disposed over the entire circumference of the second surface 995.

As shown in FIG. 17, the second S pole magnet 991 may face the first N pole magnet 952, and the second N pole magnet 992 may face the first S pole magnet 951. The numbers of the second S pole magnets 991 and the second N pole magnets 992 may be the same as or may be different from the numbers of the first S pole magnets 951 and the first N pole magnets 952.

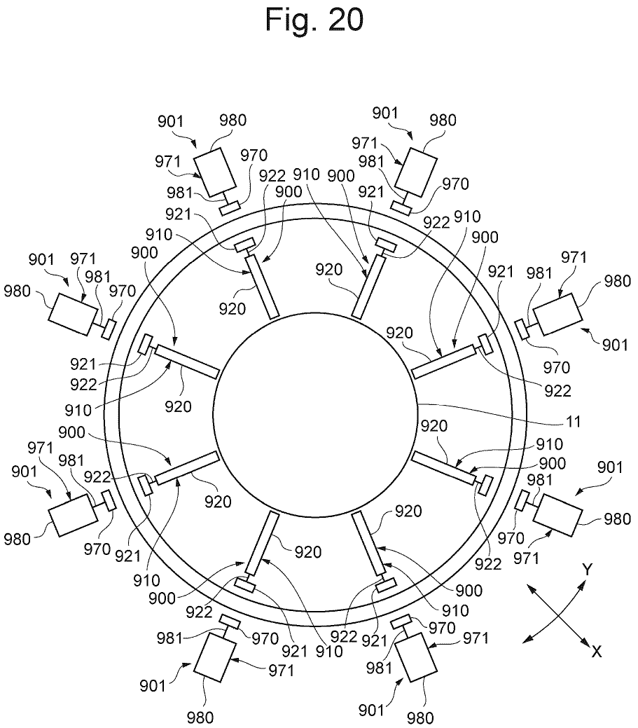

The actuator 971 may be able to rotate the first magnetic structure 921 by rotating the second magnetic structure 970, and may be able to rotate the body part 920 of the baffle structure 900 about the rotation shaft 922 by the rotation of the first magnetic structure 921. As shown in FIG. 20, the actuator 971 may be able to rotate the plate surface of the body part 920 by 90° to form an opening between the two adjacent body parts 920.

The other configurations of the plasma processing apparatus 1 may be the same as in the first embodiment and the second embodiment.

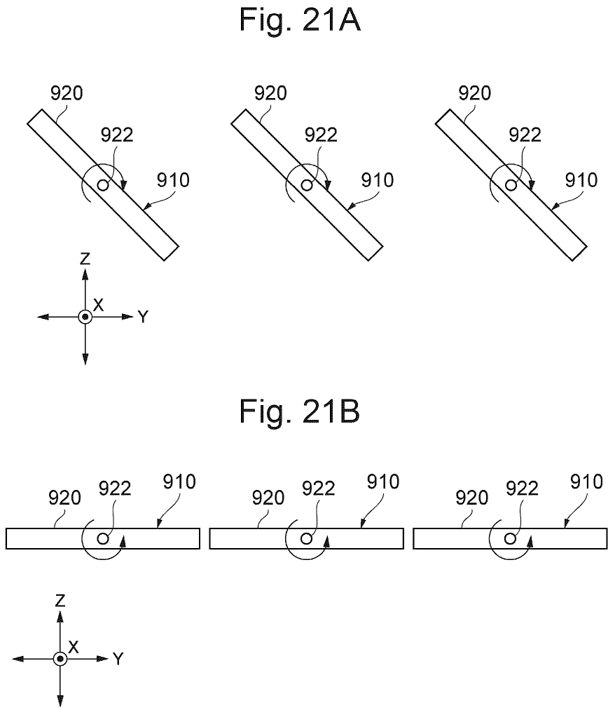

The pressure in the plasma processing space 10s during the plasma processing is adjusted by changing the rotation angle (opening degree) of the body part 920 of the baffle structure 900. As shown in FIG. 21A, in a case where the internal pressure of the plasma processing space 10s is adjusted to be relatively low, the rotation angle of the body part 920 may be made close to the vertical and the gap between the adjacent body parts 920 may be increased. As shown in FIG. 21B, in a case where the internal pressure of the plasma processing space 10s is adjusted to be relatively high, the rotation angle of the body part 920 may be made close to horizontal, and the gap between the adjacent body parts 920 may be reduced.

In this case, the second magnetic structure 970 rotates about the rotation shaft 981 in the vertical direction Z by the actuator 971 shown in FIGS. 16 and 20. Then, the first magnetic structure 921 in the chamber 10 rotates about the rotation shaft 922 in the vertical direction Z by the magnetic force of the second magnetic structure 970. As a result, the body part 920 of the baffle structure 900 rotates in the vertical direction Z, and the angle of the body part 920 is adjusted. According to the present exemplary embodiment, the plasma processing apparatus 1 includes the baffle structure 900 including a plurality of baffle segments 910, and the driving units 901 that are disposed outside the chamber 10. The driving unit 901 includes an actuator 971 configured to rotate the first magnetic structure 921 by rotating the second magnetic structure 970 and rotate the body part 920 of the baffle structure 900 about the rotation shaft 922 by the rotation of the first magnetic structure 921. As a result, in a plasma processing apparatus including the baffle structure, it is possible to reduce the contamination in the chamber 10 because it is not necessary to dispose the gear in the chamber 10 or to use the grease for the gear in the chamber 10 in order to drive the baffle structure 900.

In the third embodiment, the rotation shaft 922 may extend to the outside of the sidewall 10a of the chamber 10, and the first magnetic structure 921 may be disposed outside the sidewall 10a of the chamber 10. In this case, the driving unit 901 may directly drive the rotation shaft 922 on the outside of the sidewall 10a of the chamber 10 by using a mechanical mechanism such as a gear.

As a reference example, the driving unit 901 may be disposed inside the sidewall 10a of the chamber 10. That is, the plasma processing apparatus 1 may further include a driving unit that rotates the body part of each of the baffle segments of the baffle structure about the rotation shaft, and the driving unit may be disposed inside the sidewall 10a of the chamber 10.

The first to third embodiments described above are the capacitively-coupled plasma processing apparatus, but the present disclosure is not limited thereto, and the present disclosure may be applied to other types of plasma processing apparatuses. For example, an induction-coupled plasma processing apparatus may be used instead of the capacitively-coupled plasma processing apparatus. The above-described embodiment may be applied to a substrate processing apparatus other than the plasma processing apparatus.

The embodiments of the present disclosure further include the following aspects.

### (Addendum 1)

A substrate processing apparatus including:
a chamber having a sidewall;
a substrate support disposed in the chamber;
a first annular baffle plate disposed between the substrate support and the sidewall of the chamber, the first annular baffle plate having an upper surface and a lower surface, the first annular baffle plate having a plurality of first openings penetrating from the upper surface to the lower surface;
a second annular baffle plate disposed to overlap with the first annular baffle plate in a vertical direction, the second annular baffle plate having an upper surface, a lower surface and a first outer edge surface, the second annular baffle plate having a plurality of second openings penetrating from the upper surface to the lower surface, the second annular baffle plate including a first magnetic structure disposed on the first outer edge surface; and
a first driving unit disposed outside the chamber, the first driving unit including:
   a second magnetic structure disposed to face the first magnetic structure via the sidewall of the chamber, and
   a first actuator configured to rotate the first magnetic structure in a horizontal direction by rotating the second magnetic structure in the horizontal direction and to rotate the second annular baffle plate in the horizontal direction with respect to the first annular baffle plate by the rotation of the first magnetic structure in the horizontal direction.

### (Addendum 2)

The substrate processing apparatus according to addendum 1, in which
the first magnetic structure includes one or more first S pole magnets and one or more first N pole magnets,
the one or more first S pole magnets and the one or more first N pole magnets are alternately arranged along the horizontal direction in a first region of the first outer edge surface of the second annular baffle plate,
the second magnetic structure includes a first non-contact gear, one or more second S pole magnets, and one or more second N pole magnets,
the first non-contact gear has a second outer edge surface,
the second outer edge surface faces the first outer edge surface of the second annular baffle plate via the sidewall of the chamber, and
the one or more second S pole magnets and the one or more second N pole magnets are alternately arranged along the horizontal direction in a second region of the second outer edge surface.

### (Addendum 3)

The substrate processing apparatus according to addendum 2, in which the first S pole magnet and the first N pole magnet have lateral dimensions of 50% or less of a lateral dimension of the second opening.

### (Addendum 4)

The substrate processing apparatus according to addendum 2, in which the first S pole magnet and the first N pole magnet have lateral dimensions of 25% or less of a lateral dimension of the second opening.

### (Addendum 5)

The substrate processing apparatus according to addendum 4, in which
the first region has a lateral dimension substantially the same as the lateral dimension of the second opening,
the one or more first S pole magnets and the one or more first N pole magnets include a plurality of first S pole magnets and a plurality of first N pole magnets, and
the one or more second S pole magnets and the one or more second N pole magnets include a plurality of second S pole magnets and a plurality of second N pole magnets.

### (Addendum 6)

The substrate processing apparatus according to any one of addendums 2 to 5, in which
the second region has a lateral dimension which is the same as or larger than the lateral dimension of the first region.

### (Addendum 7)

The substrate processing apparatus according to any one of addendums 1 to 6, in which
the first annular baffle plate is fixed to the chamber, and
the second annular baffle plate is disposed below the first annular baffle plate.

### (Addendum 8)

The substrate processing apparatus according to any one of addendums 1 to 7, further including:

a second driving unit disposed outside the chamber, wherein
the second annular baffle plate includes a third magnetic structure, and
the second driving unit includes:
   a fourth magnetic structure disposed to face the third magnetic structure via the sidewall of the chamber, and
   a second actuator configured to move the third magnetic structure in the vertical direction by rotating or moving the fourth magnetic structure in the vertical direction and to move the second annular baffle plate in the vertical direction with respect to the first annular baffle plate by the movement of the third magnetic structure.

### (Addendum 9)

The substrate processing apparatus according to addendum 8, in which
the third magnetic structure includes one or more third S pole magnets and one or more third N pole magnets,
the one or more third S pole magnets and the one or more third N pole magnets are alternately arranged along the vertical direction in a third region of the first outer edge surface of the second annular baffle plate,
the fourth magnetic structure includes a second non-contact gear, one or more fourth S pole magnets, and one or more fourth N pole magnets,
the second non-contact gear has a third outer edge surface,
the third outer edge surface faces the first outer edge surface of the second annular baffle plate via the sidewall of the chamber, and
the one or more fourth S pole magnets and the one or more fourth N pole magnets are alternately arranged along the vertical direction in a fourth region of the third outer edge surface.

### (Addendum 10)

The substrate processing apparatus according to any one of addendums 1 to 7, further including:
a lifting unit disposed in the chamber and configured to move the second annular baffle plate in the vertical direction; and
a second driving unit disposed outside the chamber, wherein the lifting unit includes a third magnetic structure,
the second driving unit includes:
   a fourth magnetic structure disposed to face the third magnetic structure via the sidewall of the chamber, and
   a second actuator configured to rotate the third magnetic structure in the horizontal direction by rotating the fourth magnetic structure in the horizontal direction and to move the second annular baffle plate in the vertical direction with respect to the first annular baffle plate by the rotation of the third magnetic structure.

### (Addendum 11)

the third magnetic structure includes a second non-contact gear, one or more third S pole magnets, and one or more third N pole magnets,
the second non-contact gear has a third outer edge surface,
the one or the plurality of third S pole magnets and the one or the plurality of third N pole magnets are alternately arranged along the horizontal direction in a third region of the third outer edge surface of the second non-contact gear,
the fourth magnetic structure includes a third non-contact gear, one or more fourth S pole magnets, and one or more fourth N pole magnets,
the third non-contact gear has a fourth outer edge surface, the fourth outer edge surface faces the third outer edge surface via the sidewall of the chamber, and
the one or the plurality of fourth S pole magnets and the one or the plurality of fourth N pole magnets are alternately arranged along the horizontal direction in a fourth region of the fourth outer edge surface.

### (Addendum 12)

A substrate processing apparatus including:
a chamber having a sidewall;
a substrate support disposed in the chamber;
a first annular baffle plate disposed between the substrate support and the sidewall of the chamber, the first annular baffle plate having an upper surface and a lower surface, the first annular baffle plate having a plurality of first openings penetrating from the upper surface to the lower surface;
a second annular baffle plate disposed to overlap with the first annular baffle plate in a vertical direction, the second annular baffle plate having an upper surface, a lower surface and a first outer edge surface, the second annular baffle plate having a plurality of second openings penetrating from the upper surface to the lower surface, the second annular baffle plate including a first magnetic structure; and
a driving unit disposed outside the chamber, the driving unit including:
a second magnetic structure disposed to face the first magnetic structure via the sidewall of the chamber, and
an actuator configured to move the first magnetic structure in the vertical direction by rotating or moving the second magnetic structure in the vertical direction and to move the second annular baffle plate in the vertical direction with respect to the first annular baffle plate by the movement of the first magnetic structure.

### (Addendum 13)

The substrate processing apparatus according to addendum 12, in which
the first magnetic structure includes one or more first S pole magnets and one or more first N pole magnets,
the one or more first S pole magnets and the one or more first N pole magnets are alternately arranged along the vertical direction in a first region of the first outer edge surface of the second annular baffle plate,
the second magnetic structure includes a non-contact gear, one or more second S pole magnets, and one or more second N pole magnets,
the non-contact gear has a second outer edge surface, the second outer edge surface faces the first outer edge surface of the second annular baffle plate via the sidewall of the chamber, and
the one or more second S pole magnets and the one or more second N pole magnets are alternately arranged along the vertical direction in a second region of the second outer edge surface.

### (Addendum 14)

The substrate processing apparatus according to addendum 13, in which
the one or more first S pole magnets and the one or more first N pole magnets include a plurality of first S pole magnets and a plurality of first N pole magnets, and
the one or more second S pole magnets and the one or more second N pole magnets include a plurality of second S pole magnets and a plurality of second N pole magnets.

### (Addendum 15)

A substrate processing apparatus including:
a chamber having a sidewall;
a substrate support disposed in the chamber;
a first annular baffle plate disposed between the substrate support and the sidewall of the chamber, the first annular baffle plate having an upper surface and a lower surface, the first annular baffle plate having a plurality of first openings penetrating from the upper surface to the lower surface;
a second annular baffle plate disposed to overlap with the first annular baffle plate in a vertical direction, the second annular baffle plate having an upper surface and a lower surface, the second annular baffle plate having a plurality of second openings penetrating from the upper surface to the lower surface;
a lifting unit disposed in the chamber and configured to move the second annular baffle plate in the vertical direction, the lifting unit including a first magnetic structure; and
a driving unit disposed outside the chamber, the driving unit including:
   a second magnetic structure disposed to face the first magnetic structure via the sidewall of the chamber, and
   an actuator configured to rotate the first magnetic structure in a horizontal direction by rotating the second magnetic structure in the horizontal direction and to move the second annular baffle plate in the vertical direction with respect to the first annular baffle plate by the rotation of the first magnetic structure.

### (Addendum 16)

The substrate processing apparatus according to addendum 15, in which
the first magnetic structure includes a first non-contact gear, one or more first S pole magnets, and one or more first N pole magnets,
the first non-contact gear has a first outer edge surface,
the one or the plurality of first S pole magnets and the one or the plurality of first N pole magnets are alternately arranged along the horizontal direction in a first region of the first outer edge surface of the first non-contact gear,
the second magnetic structure includes a second non-contact gear, one or more second S pole magnets, and one or more second N pole magnets,
the second non-contact gear has a second outer edge surface, the second outer edge surface faces the first outer edge surface via the sidewall of the chamber, and
the one or the plurality of second S pole magnets and the one or the plurality of second N pole magnets are alternately arranged along the horizontal direction in a second region of the second outer edge surface.

### (Addendum 17)

The substrate processing apparatus according to addendum 16, in which
the one or more first S pole magnets and the one or more first N pole magnets include a plurality of first S pole magnets and a plurality of first N pole magnets, and
the one or more second S pole magnets and the one or more second N pole magnets include a plurality of second S pole magnets and a plurality of second N pole magnets.

### (Addendum 18)

A substrate processing apparatus including:
a chamber having a sidewall;
a substrate support disposed in the chamber;
a baffle structure disposed between the substrate support and the sidewall of the chamber, the baffle structure including a plurality of baffle segments arranged along a circumferential direction, each of the plurality of baffle segments including a body having an upper surface and a lower surface, a first magnetic structure, and a rotation shaft extending in a radial direction between the body and the first magnetic structure; and
a plurality of driving units respectively correspond to the plurality of baffle segments, the plurality of driving units being disposed outside the chamber, each of the plurality of driving units including a second magnetic structure and an actuator, the second magnetic structure being disposed to face the first magnetic structure via the sidewall of the chamber, the actuator being configured to rotate the first magnetic structure by rotating the second magnetic structure and to rotate the body part of the baffle structure about the rotation shaft by the rotation of the first magnetic structure.

### (Addendum 19)

The substrate processing apparatus according to addendum 18, in which
the first magnetic structure includes a first non-contact gear, one or more first S pole magnets, and one or more first N pole magnets,
the first non-contact gear has a first surface facing the sidewall of the chamber,
the one or the plurality of first S pole magnets and the one or the plurality of first N pole magnets are alternately arranged along a circumferential direction on the first surface of the first non-contact gear,
the second magnetic structure includes a second non-contact gear, one or more second S pole magnets, and one or more second N pole magnets,
the second non-contact gear has a second surface, and the second surface faces the first surface of the first non-contact gear via the sidewall of the chamber, and
the one or the plurality of second S pole magnets and the one or the plurality of second N pole magnets are alternately arranged along the circumferential direction on the second surface of the second non-contact gear.

### (Addendum 20)

The substrate processing apparatus according to addendum 19, in which
the one or more first S pole magnets and the one or more first N pole magnets include a plurality of first S pole magnets and a plurality of first N pole magnets, and
the one or more second S pole magnets and the one or more second N pole magnets include a plurality of second S pole magnets and a plurality of second N pole magnets.

Each of the above embodiments is described for the purpose of description, and is not intended to limit the scope of the present disclosure. Each of the above embodiments may be modified in various ways without departing from the scope and purpose of the present disclosure. For example, some elements in one embodiment can be added to other embodiments. In addition, some elements in one embodiment can be replaced with corresponding elements in other embodiments.

According to one exemplary embodiment of the present disclosure, it is possible to provide a technique capable of reducing contamination in a chamber in a substrate processing apparatus including a baffle structure.

What is claimed is:

1. A substrate processing apparatus comprising:
a chamber having a sidewall;
a substrate support disposed in the chamber;
a first annular baffle plate disposed between the substrate support and the sidewall of the chamber, the first annular baffle plate having an upper surface and a lower surface, the first annular baffle plate having a plurality of first openings penetrating from the upper surface to the lower surface;
a second annular baffle plate disposed to overlap with the first annular baffle plate in a vertical direction, the second annular baffle plate having an upper surface, a lower surface and a first outer edge surface, the second annular baffle plate having a plurality of second openings penetrating from the upper surface to the lower surface, the second annular baffle plate including a first magnetic structure disposed on the first outer edge surface; and
a first driving unit disposed outside the chamber, the first driving unit including:
a second magnetic structure disposed to face the first magnetic structure via the sidewall of the chamber, and
a first actuator configured to rotate the first magnetic structure in a horizontal direction by rotating the second magnetic structure in the horizontal direction and to rotate the second annular baffle plate in the horizontal direction with respect to the first annular baffle plate by the rotation of the first magnetic structure in the horizontal direction.

2. The substrate processing apparatus according to claim 1, wherein
the first magnetic structure includes one or more first S pole magnets and one or more first N pole magnets,
the one or more first S pole magnets and the one or more first N pole magnets are alternately arranged along the horizontal direction in a first region of the first outer edge surface of the second annular baffle plate,
the second magnetic structure includes a first non-contact gear, one or more of second S pole magnets, and one or more second N pole magnets,
the first non-contact gear has a second outer edge surface,
the second outer edge surface faces the first outer edge surface of the second annular baffle plate via the sidewall of the chamber, and
the one or more second S pole magnets and the one or more second N pole magnets are alternately arranged along the horizontal direction in a second region of the second outer edge surface.

3. The substrate processing apparatus according to claim 2, wherein
the first S pole magnet and the first N pole magnet have lateral dimensions of 50% or less of a lateral dimension of the second opening.

4. The substrate processing apparatus according to claim 2, wherein
the first S pole magnet and the first N pole magnet have lateral dimensions of 25% or less of a lateral dimension of the second opening.

5. The substrate processing apparatus according to claim 4, wherein
the first region has a lateral dimension substantially the same as the lateral dimension of the second opening,
the one or more first S pole magnets and the one or more first N pole magnets include a plurality of first S pole magnets and a plurality of first N pole magnets, and
the one or more second S pole magnets and the one or more second N pole magnets include a plurality of second S pole magnets and a plurality of second N pole magnets.

6. The substrate processing apparatus according to claim 5, wherein
the second region has a lateral dimension which is the same as or larger than the lateral dimension of the first region.

7. The substrate processing apparatus according to claim 1, wherein
the first annular baffle plate is fixed to the chamber, and
the second annular baffle plate is disposed below the first annular baffle plate.

8. The substrate processing apparatus according to claim 7, further comprising:
a second driving unit disposed outside the chamber, wherein
the second annular baffle plate includes a third magnetic structure, and
the second driving unit includes:
a fourth magnetic structure disposed to face the third magnetic structure via the sidewall of the chamber, and
a second actuator configured to move the third magnetic structure in the vertical direction by rotating or moving the fourth magnetic structure in the vertical direction and to move the second annular baffle plate in the vertical direction with respect to the first annular baffle plate by the movement of the third magnetic structure.

9. The substrate processing apparatus according to claim 8, wherein
the third magnetic structure includes one or more third S pole magnets and one or more third N pole magnets,
the one or more third S pole magnets and the one or more third N pole magnets are alternately arranged along the vertical direction in a third region of the first outer edge surface of the second annular baffle plate,
the fourth magnetic structure includes a second non-contact gear, one or more fourth S pole magnets, and one or more fourth N pole magnets,
the second non-contact gear has a third outer edge surface,
the third outer edge surface faces the first outer edge surface of the second annular baffle plate via the sidewall of the chamber, and
the one or more fourth S pole magnets and the one or more fourth N pole magnets are alternately arranged along the vertical direction in a fourth region of the third outer edge surface.

10. The substrate processing apparatus according to claim 7, further comprising:
a lifting unit disposed in the chamber and configured to move the second annular baffle plate in the vertical direction; and
a second driving unit disposed outside the chamber, wherein
the lifting unit includes a third magnetic structure,
the second driving unit includes:
a fourth magnetic structure disposed to face the third magnetic structure via the sidewall of the chamber, and
a second actuator configured to rotate the third magnetic structure in the horizontal direction by rotating the fourth magnetic structure in the horizontal direction and to move the second annular baffle plate in the vertical direction with respect to the first annular baffle plate by the rotation of the third magnetic structure.

11. The substrate processing apparatus according to claim 10, wherein
the third magnetic structure includes a second non-contact gear, one or more third S pole magnets, and one or more third N pole magnets,
the second non-contact gear has a third outer edge surface,
the one or more third S pole magnets and the one or more third N pole magnets are alternately arranged along the horizontal direction in a third region of the third outer edge surface of the second non-contact gear,
the fourth magnetic structure includes a third non-contact gear, one or more fourth S pole magnets, and one or more fourth N pole magnets,
the third non-contact gear has a fourth outer edge surface, the fourth outer edge surface faces the third outer edge surface via the sidewall of the chamber, and
the one or more fourth S pole magnets and the one or more fourth N pole magnets are alternately arranged along the horizontal direction in a fourth region of the fourth outer edge surface.

12. A substrate processing apparatus comprising:
a chamber having a sidewall;
a substrate support disposed in the chamber;
a first annular baffle plate disposed between the substrate support and the sidewall of the chamber, the first annular baffle plate having an upper surface and a lower surface, the first annular baffle plate having a plurality of first openings penetrating from the upper surface to the lower surface;
a second annular baffle plate disposed to overlap with the first annular baffle plate in a vertical direction, the second annular baffle plate having an upper surface, a lower surface and a first outer edge surface, the second annular baffle plate having a plurality of second openings penetrating from the upper surface to the lower surface, the second annular baffle plate including a first magnetic structure; and
a driving unit disposed outside the chamber, the driving unit including:
a second magnetic structure disposed to face the first magnetic structure via the sidewall of the chamber, and
an actuator configured to move the first magnetic structure in the vertical direction by rotating or moving the second magnetic structure in the vertical direction and to move the second annular baffle plate in the vertical direction with respect to the first annular baffle plate by the movement of the first magnetic structure.

13. The substrate processing apparatus according to claim 12, wherein
the first magnetic structure includes one or more first S pole magnets and one or more first N pole magnets,
the one or more first S pole magnets and the one or more first N pole magnets are alternately arranged along the vertical direction in a first region of the first outer edge surface of the second annular baffle plate,
the second magnetic structure includes a non-contact gear, one or more second S pole magnets, and one or more second N pole magnets,
the non-contact gear has a second outer edge surface, the second outer edge surface faces the first outer edge surface of the second annular baffle plate via the sidewall of the chamber, and
the one or more second S pole magnets and the one or more second N pole magnets are alternately arranged along the vertical direction in a second region of the second outer edge surface.

14. The substrate processing apparatus according to claim 13, wherein
the one or more first S pole magnets and the one or more first N pole magnets include a plurality of first S pole magnets and a plurality of first N pole magnets, and
the one or more second S pole magnets and the one or more second N pole magnets include a plurality of second S pole magnets and a plurality of second N pole magnets.

15. A substrate processing apparatus comprising:
a chamber having a sidewall;
a substrate support disposed in the chamber;
a first annular baffle plate disposed between the substrate support and the sidewall of the chamber, the first annular baffle plate having an upper surface and a lower surface, the first annular baffle plate having a plurality of first openings penetrating from the upper surface to the lower surface;
a second annular baffle plate disposed to overlap with the first annular baffle plate in a vertical direction, the second annular baffle plate having an upper surface and a lower surface, the second annular baffle plate having a plurality of second openings penetrating from the upper surface to the lower surface;
a lifting unit disposed in the chamber and configured to move the second annular baffle plate in the vertical direction, the lifting unit including a first magnetic structure; and
a driving unit disposed outside the chamber, the driving unit including:
a second magnetic structure disposed to face the first magnetic structure via the sidewall of the chamber, and
an actuator configured to rotate the first magnetic structure in a horizontal direction by rotating the second magnetic structure in the horizontal direction and to move the second annular baffle plate in the vertical direction with respect to the first annular baffle plate by the rotation of the first magnetic structure.

16. The substrate processing apparatus according to claim 15, wherein
the first magnetic structure includes a first non-contact gear, one or more first S pole magnets, and one or more first N pole magnets,
the first non-contact gear has a first outer edge surface,
the one or more first S pole magnets and the one or more first N pole magnets are alternately arranged along the horizontal direction in a first region of the first outer edge surface of the first non-contact gear,
the second magnetic structure includes a second non-contact gear, one or more second S pole magnets, and one or more second N pole magnets,
the second non-contact gear has a second outer edge surface, the second outer edge surface faces the first outer edge surface via the sidewall of the chamber, and
the one or more second S pole magnets and the one or more second N pole magnets are alternately arranged along the horizontal direction in a second region of the second outer edge surface.

17. The substrate processing apparatus according to claim 16, wherein
the one or more first S pole magnets and the one or more first N pole magnets include a plurality of first S pole magnets and a plurality of first N pole magnets, and
the one or more second S pole magnets and the one or more second N pole magnets include a plurality of second S pole magnets and a plurality of second N pole magnets.

18. A substrate processing apparatus comprising:
a chamber having a sidewall;
a substrate support disposed in the chamber;
a baffle structure disposed between the substrate support and the sidewall of the chamber, the baffle structure including a plurality of baffle segments arranged along a circumferential direction, each of the plurality of baffle segments including a body having an upper surface and a lower surface, a first magnetic structure, and a rotation shaft extending in a radial direction between the body and the first magnetic structure; and
a plurality of driving units respectively correspond to the plurality of baffle segments, the plurality of driving units being disposed outside the chamber, each of the plurality of driving units including a second magnetic structure and an actuator, the second magnetic structure being disposed to face the first magnetic structure via the sidewall of the chamber, the actuator being configured to rotate the first magnetic structure by rotating the second magnetic structure and to rotate the body part of the baffle structure about the rotation shaft by the rotation of the first magnetic structure.

19. The substrate processing apparatus according to claim 18, wherein
the first magnetic structure includes a first non-contact gear, one or more first S pole magnets, and one or more first N pole magnets,
the first non-contact gear has a first surface facing the sidewall of the chamber,
the one or more first S pole magnets and the one or more first N pole magnets are alternately arranged along a circumferential direction on the first surface of the first non-contact gear,
the second magnetic structure includes a second non-contact gear, one or more second S pole magnets, and one or more second N pole magnets,
the second non-contact gear has a second surface, and the second surface faces the first surface of the first non-contact gear via the sidewall of the chamber, and
the one or more second S pole magnets and the one or more second N pole magnets are alternately arranged along the circumferential direction on the second surface of the second non-contact gear.

20. The substrate processing apparatus according to claim 19, wherein
the one or more first S pole magnets and the one or more first N pole magnets include a plurality of first S pole magnets and a plurality of first N pole magnets, and
the one or more second S pole magnets and the one or more second N pole magnets include a plurality of second S pole magnets and a plurality of second N pole magnets.
